(19) United States
(12) Patent Application Publication
(10) Pub. No.: US 2025/0370012 A1
(43) Pub. Date: Dec. 4, 2025

(54) CURRENT SENSOR

(71) Applicant: EG KOREA, Cheongju-si (KR)

(72) Inventors: Chul Bum JOO, Busan (KR); Bong Jun KIM, Daejeon (KR); Chang Ha KIM, Busan (KR); Tae Woo KIM, Seoul (KR)

(21) Appl. No.: 19/301,741

(22) Filed: Aug. 15, 2025

Related U.S. Application Data
(63) Continuation of application No. PCT/KR2024/016718, filed on Oct. 30, 2024.

(30) Foreign Application Priority Data
Mar. 19, 2024 (KR) 10-2024-0038102
Aug. 4, 2024 (KR) 10-2024-0103535

(51) Int. Cl. G01R 19/00; G01R 15/20

(52) U.S. Cl. CPC G01R 19/0046; G01R 15/207

(57) ABSTRACT

A current sensor includes a sensor unit including at least one coil formed of a substrate including an insulating layer and conductor layers sandwiching the insulating layer, a plurality of via holes each including a conductive film on an inner wall penetrating the substrate, and a line patterning formed on the conductor layers to electrically connect the plurality of via holes. The sensor also includes a circuit unit disposed in proximity to the sensor unit on the substrate and configured to output a detection signal from the sensor unit to an outside, and a connection unit electrically connecting the sensor unit and the circuit unit. A width of each of the sensor unit and the circuit unit in a transverse direction of the power line is equal to or less than a width of the power line. The circuit unit overlaps the power line.

### CROSS-REFERENCE TO RELATED APPLICATIONS

This application is a continuation of International Application No. PCT/KR2024/016718, filed Oct. 30, 2024, which claims the benefit of priority from Korean Patent Application No. 10-2024-0038102, filed on Mar. 19, 2024 and Korean Patent Application No. 10-2024-0103535, filed on Aug. 4, 2024, the contents of each of which are incorporated herein by reference in their entirety.

### BACKGROUND

### Technical Field

The present disclosure relates to a current sensor.

### 2. DESCRIPTION OF RELATED TECHNOLOGY

Accurate measurement of current flowing through power lines is a critical element in maximizing power efficiency through power demand forecast and analysis, as well as protecting power systems through fault current detection and rapid isolation of faulty systems.

### SUMMARY

One aspect is a current sensor for measuring a current flowing through a power line that includes a sensor unit including at least one coil formed of a substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit disposed in proximity to the sensor unit on the first conductor layer or the second conductor layer and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The circuit unit overlaps the power line. The sensor unit and the circuit unit are arranged in alignment along the longitudinal direction of the power line.

Another aspect is a current sensor for measuring a current flowing through a power line that includes a sensor unit including at least one coil formed of a substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit disposed in proximity to the sensor unit on the first conductor layer or the second conductor layer and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The circuit unit overlaps the power line. The sensor unit and the circuit unit are arranged in alignment along the transverse direction of the power line.

Another aspect is a current sensor for measuring a current flowing through a power line that includes a sensor unit including at least one coil formed of a first substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit formed on a second substrate of a same type as the first substrate and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The first substrate and the second substrate are disposed so as to be stacked in a direction normal to each other.

While each embodiment is described independently in the present specification, they may be combined in various ways, and such combinations are also encompassed within the scope of the present disclosure.

It is to be understood that the foregoing summary is intended merely to facilitate understanding and is not to be construed as limiting in any respect. Additional aspects, embodiments, and features will be apparent from the drawings and the detailed description set forth below.

### BRIEF DESCRIPTION OF THE DRAWINGS

FIGS. 1 to 3 are schematic diagrams showing a current sensor mounted on a power line according to at least one embodiment of the present disclosure.

FIG. 4 is a perspective view of a sensor unit of a current sensor according to at least one embodiment of the present disclosure.

FIG. 5 is a plan view showing first and second surfaces of the sensor unit of the current sensor according to at least one embodiment of the present disclosure.

FIG. 6 is a perspective view showing a coil configuration of the sensor unit of the current sensor according to at least one embodiment of the present disclosure.

FIG. 7 is an exploded perspective view of a current sensor according to at least one embodiment of the present disclosure.

FIG. 8 is a perspective view showing a process of mounting a current sensor on a power line according to at least one embodiment of the present disclosure.

FIG. 9 is a perspective view showing a current sensor mounted on a power line according to at least one embodiment of the present disclosure.

FIG. 10 is an exploded perspective view showing an assembly process of a current sensor according to at least one embodiment of the present disclosure.

FIG. 11 is a cross-sectional side view showing a current sensor mounted on a power line according to at least one embodiment of the present disclosure.

FIGS. 12A and 12B are side views each showing a configuration in which a current sensor, according to at least one embodiment of the present disclosure, is mounted on a power line.

FIG. 13 is a measurement graph for comparing the current detection performance of a current sensor according to at least one embodiment of the present disclosure and a current sensor according to Korean Patent No. 10-1981640.

FIG. 14 is a measurement graph showing the noise characteristics of a current sensor according to at least one embodiment of the present disclosure.

FIG. 15 is a measurement graph showing the unsaturation characteristics of a current sensor according to at least one embodiment of the present disclosure. and

FIGS. 16 and 17 are perspective views showing coil configurations of sensor units of current sensors according to at least one embodiment of the present disclosure.

### DETAILED DESCRIPTION

Current sensors used to detect current flowing through a target power line can be categorized into two types: resistance detection using shunt resistors and magnetic detection using the magnetic field surrounding the power line. The magnetic detection methods can be categorized into sensors using current transformers (CTs) and sensors using Hall elements.

The CTs utilize the principle of a transformer and are generally used to measure AC current, which varies over time. When current flows through a power line, a magnetic field is generated around it. When the power line passes through a donut-shaped CT, the magnetic field around the power line induces an induced current in the CT coil.

A Hall element utilizes the Hall effect, which generates an electromotive force in a direction perpendicular to the current and the magnetic field when a magnetic field is applied perpendicular to the current. Sensors utilizing this Hall effect are referred to as Hall sensors, and a detection signal is generated by changes in the magnetic field of a magnetic object.

A Rogowski coil current sensor, which is another type of magnetic field detection method, measures current by converting the voltage induced in an air-core coil by the AC magnetic field generated around the current being measured. Specifically, the magnetic field caused by the AC current flowing in the target power line (primary side) links with the air-core coil, generating an induced voltage in the air-core coil. This induced voltage becomes the time derivative of the measured current, and is passed through an integrator to output a signal proportional to the measured current.

As another method, a current sensor is disclosed that detects AC current by positioning the sensor at a predetermined distance from a power line carrying AC current, and measuring the electromagnetic waves generated in the sensor by the induced electromotive force generated by the AC current flowing in the power line (see, for example, Korean Patent No. 10-1981640).

In order to reduce the size of the current sensor, one can use the current sensor disclosed in Korean Patent No. 10-1981640 or a current sensor utilizing a Hall element. However, the current sensor disclosed in Korean Patent No. 10-1981640 includes a non-coil measurement lead arranged parallel to the power line, resulting in a significantly low measurement sensitivity at low currents (for example, 1 A or less).

Hall elements require a magnetic core, limiting their miniaturization (see, for example, Korean Patent No. 10-0897229). Not only that, because they are sensitive to magnetic signals, they are susceptible to noise. Unless completely shielded, the induced magnetic field generated by the active state of a neighboring busbar can be incorporated into the noise, increasing measurement error.

Furthermore, most current sensors using magnetic field detection require power lines to pass through the core, making them difficult to mount on existing power lines and requiring a large mounting area.

In terms of the mounting area, printed circuit boards with CT functionality are described to address spatial constraints for power line installation. However, since these target high-frequency power in the Radio Frequency (RF) band with frequencies ranging from hundreds of kHz to several GHz, current detection is possible even when a metal shield is placed between the power line and the coil to block the electric field (see, for example, Japanese Patent Application Laid-Open Publication No. 2015-200631).

However, for low-frequency power with a commercial frequency of 50 Hz or 60 Hz, unlike high-frequency power in the RF band, the level of induced current due to magnetic flux generated in the power line does not differ significantly from the ambient (atmospheric) noise level. Therefore, measuring current flowing in the power line using a structure similar to the CT-function printed circuit board described in Japanese Patent Application Laid-Open Publication No. 2015-200631 poses a challenge.

Hereinafter, embodiments of the present disclosure will be described in detail with reference to the accompanying drawings.

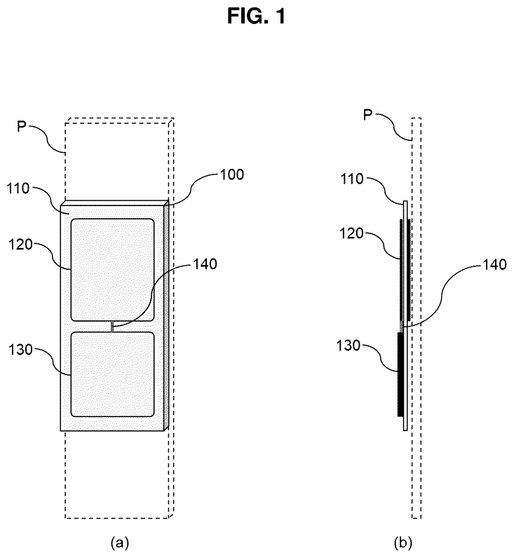

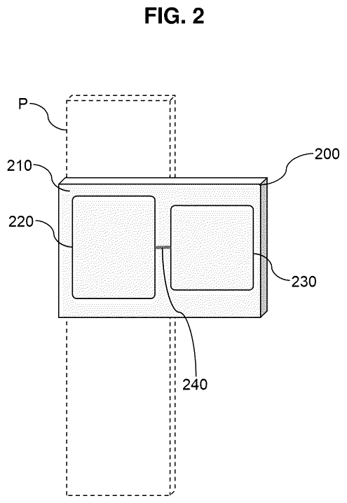

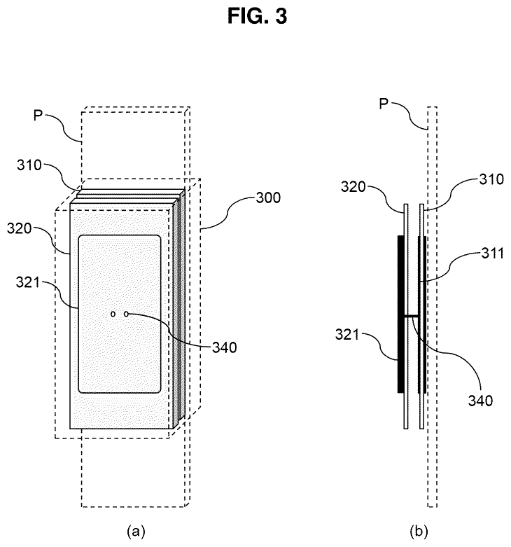

FIG. 1 is a schematic diagram showing a current sensor 100 mounted on a power line (for example, a busbar) P according to at least one embodiment of the present disclosure. FIG. 2 is a schematic diagram showing a current sensor 200 mounted on a power line P according to at least one embodiment of the present disclosure. FIG. 3 is a schematic diagram showing a current sensor 300 mounted on a power line P according to at least one embodiment of the present disclosure.

In FIGS. 1 and 3, (a) is a perspective view close to a plan view from above of a current sensor mounted on the power line P, and (b) is a side view of a current sensor mounted on the power line P.

The current sensor 100 illustrated in FIG. 1 includes a substrate 110 including conductor layers respectively formed on both sides of an insulating layer with the insulating layer therebetween, a sensor unit 120 formed on the substrate 110, a circuit unit 130 formed on the same substrate 110 as the sensor unit 120 to receive an output from the sensor unit 120 and to output a current signal representing the intensity of the current flowing in the power line through a predetermined signal processing, and a connection unit 140 for electrically connecting the sensor unit 120 and the circuit unit 130.

When current flows in the power line P, a magnetic field is formed around the power line P, and the sensor unit 120 detects the magnetic flux flowing along the magnetic field and outputs a signal representing the intensity of the current flowing in the power line P.

At this time, since the sensor unit 120 detects the magnetic flux caused by the low-frequency current flowing in the power line P, the level of the detected signal does not differ significantly from the noise level (in the air) around the power line P, so in order to minimize the influence on the signal level of the sensor unit 120, it is necessary to form a line parallel to the power line P as short as possible inside the current sensor 100.

This is because, as described in Korean Patent No. 10-1981640, a transmission line parallel to the power line (P) may serve as a different current detection source from the sensor unit 120, and therefore, it is intended to prevent such influence from affecting the signal level of the sensor unit 120.

Therefore, by minimizing the length of the output terminal line of the sensor unit 120 and the connection unit 140 that electrically connects the sensor unit 120 and the circuit unit 130 (minimizing the distance between the sensor unit 120 and the circuit unit 130), the signal detection efficiency of the sensor unit 120 can be improved.

Referring to FIG. 1, a current sensor according to at least one embodiment of the present disclosure is configured to measure a current flowing through a power line. The current sensor includes a sensor unit including at least one coil formed of a substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit disposed in proximity to the sensor unit on the first conductor layer or the second conductor layer and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The circuit unit overlaps the power line. The sensor unit and the circuit unit are arranged in alignment along the longitudinal direction of the power line.

The current sensor 200 illustrated in FIG. 2 includes a substrate 210 including conductor layers respectively formed on both sides of an insulating layer with the insulating layer therebetween, a sensor unit 220 formed on the substrate 210, a circuit unit 230 formed on the same substrate 210 as the sensor unit 220 to receive an output from the sensor unit 220 and to output a current signal representing the intensity of a current flowing in a power line through a predetermined signal processing, and a connection unit 240 for electrically connecting the sensor unit 220 and the circuit unit 230.

While the current sensor 100 illustrated in FIG. 1 is configured with the sensor unit 120 formed along the power line P, the circuit unit 130, and the connection unit 140 for electrically connecting the sensor unit 120 and the circuit unit 130 in the direction of the power line P, in the current sensor 200 illustrated in FIG. 2, the sensor unit 220 and the circuit unit 230 are formed on the same substrate 210, but the sensor unit 220 and the circuit unit 230 are arranged in a direction perpendicular to the power line P, so that the connection unit 240 is configured to electrically connect the sensor unit 220 and the circuit unit 230 in a direction perpendicular to the power line P.

The current sensor 200 illustrated in FIG. 2 has a disadvantage in that the current sensor itself is stuck out of the power line P and thus requires more space on the side of the power line P, but has an advantage in that, compared to the current sensor 100 illustrated in FIG. 1, the signal detection efficiency of the sensor unit 220 can be further improved because lines parallel to the power line P can be more excluded.

Referring to FIG. 2, a current sensor according to at least one embodiment of the present disclosure is configured to measure a current flowing through a power line. The current sensor includes a sensor unit including at least one coil formed of a substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit disposed in proximity to the sensor unit on the first conductor layer or the second conductor layer and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The circuit unit overlaps the power line. The sensor unit and the circuit unit are arranged in alignment along the transverse direction of the power line.

The current sensor 300 illustrated in FIG. 3 includes a first substrate 310 including conductor layers respectively formed on both sides of an insulating layer with the insulating layer therebetween, a sensor unit 311 formed on the first substrate 310, a second substrate 320 including conductor layers respectively formed on both sides of an insulating layer with the insulating layer therebetween, a circuit unit 321 formed on the second substrate 320 to receive an output from the sensor unit 311 and to output a current signal representing the intensity of the current flowing in the power line through predetermined signal processing, and a connection unit 340 for electrically connecting the sensor unit 311 and the circuit unit 321.

While the current sensor 100 illustrated in FIG. 1 and the current sensor 200 illustrated in FIG. 2 have a structure in which the sensor unit and the circuit unit are formed on the same substrate, the current sensor 300 illustrated in FIG. 3 has a structure in which the sensor unit 311 and the circuit unit 321 are respectively formed on separate, independent substrates and are electrically connected by the connection unit 340 as if they are laminated in one direction normal to the power line P. At this time, the connection unit 340 can electrically connect the sensor unit 311 and the circuit unit 321 and also perform the function of physically fixing them.

In this manner, the sensor unit 311 and the circuit unit 321 are respectively formed on separate, independent substrates and electrically connected by the connection unit 340 as if they are laminated in one direction normal to the power line P, thereby minimizing the distance between the sensor unit 311 and the circuit unit 321 while eliminating lines parallel to the power line P, thereby further improving the signal detection efficiency of the sensor unit 311.

At this time, the connection unit 340 needs to be formed as short as possible (minimizing its length) while electrically connecting the sensor unit 311 and the circuit unit 321 and simultaneously securing them so that they do not physically contact each other.

Referring to FIG. 3, a current sensor according to at least one embodiment of the present disclosure is configured to measure a current flowing through a power line. The current sensor includes a sensor unit including at least one coil formed of a first substrate including an insulating layer and a first conductor layer and a second conductor layer respectively formed on both surfaces of the insulating layer, a plurality of via holes each having a conductive film on an inner wall thereof formed so as to penetrate the insulating layer, the first conductor layer, and the second conductor layer, and a line patterning formed on the first and second conductor layers to electrically connect the plurality of via holes, a circuit unit formed on a second substrate of a same type as the first substrate and configured to output a detection signal from the sensor unit to an outside, and a connection unit configured to electrically connect the sensor unit and the circuit unit. A width of the sensor unit and a width of the circuit unit in a transverse direction of the power line, which is perpendicular to a longitudinal direction of the power line through which the current flows, are each formed to be equal to or less than a width of the power line. The first substrate and the second substrate are disposed so as to be stacked in a direction normal to each other.

As illustrated in FIGS. 1 to 3, the current sensors 100, 200, 300 are configured to be mounted on a power line (for example, a busbar) P and are configured to measure the induced current caused by the change in magnetic flux that occurs when current flows in the power line P.

To this end, each of the sensor units 120, 220, 311 is configured to include at least one coil formed by a plurality of via holes having conductive films formed on the inner walls and penetrating the insulating layer and the conductor layer of the substrate and a line patterning formed to connect the plurality of via holes to the conductor layer.

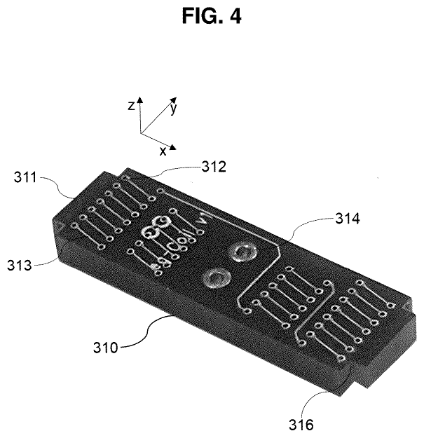

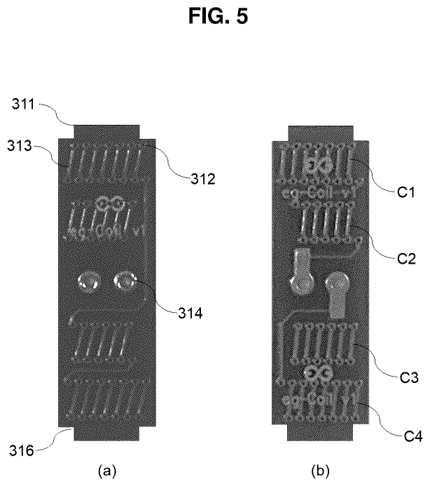

FIGS. 4 and 5 are actual images of the first substrate 310 manufactured in the form of the current sensor 300 illustrated in FIG. 3, in which a plurality of via holes 312 and a line patterning 313 are formed on a PCB having a thickness of 2 mm and a length of 7 mm×22 mm in the y and x directions to form a coil C1 having 7 turns, a coil C2 having 5 turns, a coil C3 having 6 turns, and a coil C4 having 7 turns.

In the sensor unit 311 illustrated in FIGS. 4 and 5, the four coils C1 to C4 formed are connected in series with each other and configured to maximize the induced electromotive force due to the magnetic flux generated by the current flowing in the power line P with the substrate of a predetermined size.

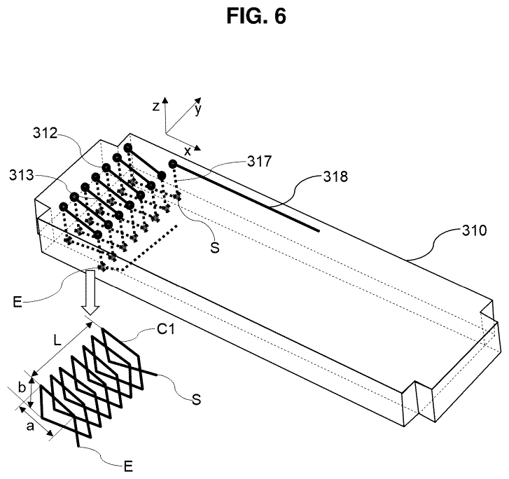

FIG. 6 is a perspective view showing the coil formation of the sensor unit 311 of the current sensor 300 according to at least one embodiment of the present disclosure. The sensor unit 120 of the current sensor 100 and the sensor unit 220 of the current sensor 200 may also form coils in the same manner as the sensor unit 311.

As illustrated in FIG. 6, a conductive film 317 is formed within each of the plurality of via holes 312 formed in a zigzag shape or in two rows in a straight line in the first direction (y-direction) on the first substrate 310. Therefore, when the line patterning 313 is formed to electrically connect the via holes 312 on both sides in a spiral shape, as illustrated under the arrow in FIG. 6, a coil C1 having a length L and a major axis length a is formed through a spiral structure between a starting point S and an ending point E. At this time, the minor axis length b of the coil C1 corresponds to the thickness of the first substrate 310.

In at least one embodiment of the present disclosure, the coils C1 to C4 may include an iron core or a magnetized core (collectively, “a metal core”, not illustrated) at the center. While a coreless coil has the advantage of not being saturated, a coil with an iron core has the disadvantage of being saturated when the magnetic flux density of the iron core reaches its maximum, but has the advantage of increased sensitivity.

In at least one embodiment of the present disclosure, each of the substrates 110, 210, 310, 320 includes a printed circuit board (PCB) in which an insulating layer and a conductor layer are laminated in a substrate form, and a desired circuit can be configured by patterning the conductor layer.

In at least one embodiment of the present disclosure, the plurality of via holes are formed in two rows parallel to the first direction (the y-direction in the example illustrated in FIG. 6), as illustrated in FIG. 6.

Generally, in the case of low-frequency power having a commercial frequency (or power frequency) of 50 Hz or 60 Hz, unlike high-frequency power in the RF band, the level of induced current due to magnetic flux generated in the power line does not differ significantly from the ambient (atmospheric) noise level, making it hard to measure the current flowing in the power line.

To address this issue, the present disclosure, in at least one embodiment, improves the signal detection efficiency of the sensor unit to a commercial level through the following structure.
i) When creating a wire pattern for coil formation in the sensor unit, the length of the wire parallel to the power line (for example, wire 318 in FIG. 6) should be as short as possible (or minimized).
ii) The distance between the sensor unit and the circuit unit should be as short as possible (or minimized).
iii) When forming the sensor unit and the circuit unit on separate substrates, to minimize the influence of wires other than the coils when forming multiple coils, the sensor unit output terminal should be positioned at the center of the multiple coils, or the output terminals should be positioned at each edge of the substrate. The latter approach ensures the shortest distance between the sensor unit and the circuit unit.
iv) When forming the sensor unit and the circuit unit on separate substrates, the sensor unit and the circuit unit should be positioned close together in a direction normal to the power line.
v) A shielding case in the form of a metal box should be provided to minimize the influence of external noise.
vi) Both the sensor unit and the circuit unit should be housed within the shielding case.
vii) The circuit unit includes at least a low pass filter and an amplifier.

As described above, in the case of low-frequency power in the commercial frequency band of 50 Hz or 60 Hz, unlike high-frequency power in the RF band, the level of induced current generated by the magnetic flux from the power line does not significantly differ from the ambient (atmospheric) noise level. Furthermore, during the formation of the coil pattern in the sensor unit, a transmission line running parallel to the power line in the coil-forming pattern, in the connection between the sensor unit and the circuit unit, or within the circuit unit itself—can serve as an additional noise source, distinct from ambient noise, by detecting current signals unrelated to the sensor unit.

Accordingly, in at least one embodiment of the present disclosure, in order to address the above issues, a plurality of coils are connected in series or in parallel to increase the signal level of the sensor unit. Additionally, the length of transmission lines running parallel to the power line including those used for coil patterning in the sensor unit, those connecting the sensor unit to the circuit unit, and those connecting the circuit unit to an external device—is minimized. The distance between the sensor unit and the circuit unit is also reduced as much as possible, thereby enabling efficient transmission of current signals from the sensor unit to the circuit unit.

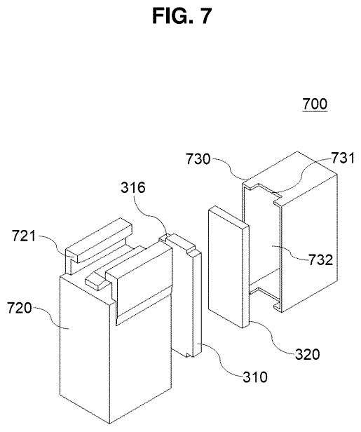

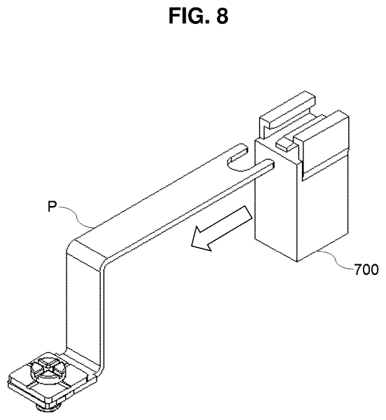

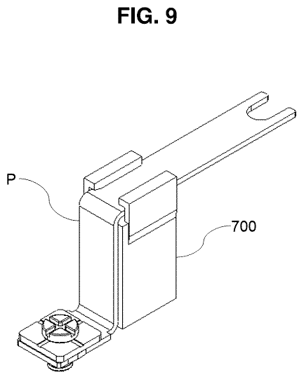

FIG. 7 is an exploded perspective view of a current sensor 700 according to at least one embodiment of the present disclosure. FIG. 8 is a perspective view showing a process of mounting the current sensor 700 according to at least one embodiment of the present disclosure on a power line P. FIG. 9 is a perspective view showing a state in which the current sensor 700 according to at least one embodiment of the present disclosure is mounted on the power line P.

In at least one embodiment of the present disclosure, as illustrated in FIG. 7, the current sensor 700 further includes a shielding case 730 made of a conductive (metal) material configured in a box shape with an opening 732 on a first side.

A shielding case 730 according to at least one embodiment of the present disclosure is configured in a box shape made of a conductive material to block external noise entering from all directions, and is intended to shield external noise when detecting magnetic flux of a power line transmitting low-frequency (for example, commercial frequency) power.

In at least one embodiment of the present disclosure, the first substrate 310 is formed in a cross shape with L-shaped grooves 316 formed at four corners of a square, and both sides facing each other protrude by the amount of the L-shaped grooves 316.

The shielding case 730 is configured such that both sides protruding in a second direction (x direction in FIG. 6) perpendicular to the first direction of the first substrate 310 are fitted with recessed portions 731 on both sides facing the second direction of the opening 732, so that when both sides protruding in the second direction of the first substrate 310 are fitted into the recessed portions 731 of the opening 732, both sides of the first substrate 310 in the first direction are inserted into the opening 732 to block the opening 732.

Therefore, when the shielding case 730 is mounted on the power line P such that the first substrate 310 is brought close to the power line P, the shielding case 730 shields the outer surface of the first substrate 310 (the side opposite the power line P), and the power line P itself serves to shield the side of the power line P.

With this structure, in order to shield the four sides of the sensor unit 311 while allowing the magnetic flux generated when current flows in the power line P to enter the coils C1 to C4 of the sensor unit 311, the width (length in the first direction) of the sensor unit 311 needs to be set to be less than or equal to the width of the power line P.

In at least one embodiment of the present disclosure, the sensor unit 311 is arranged inside the shielding case 730 in a direction in which the magnetic flux generated in the power line P is best transmitted, so that the magnetic change generated in the power line P is efficiently detected.

In at least one embodiment of the present disclosure, the current sensor 700, as illustrated in FIG. 7, is configured in a box shape with one side open so that the opening 732 of the shielding case 730 can be inserted, and further includes an insulating mounting member 720 having a fastening member 721 on the outer surface thereof so as to be fitted to the power line P.

The current sensor 700 illustrated in FIGS. 7 to 9 is described using the structure of the current sensor 300 illustrated in FIG. 3 as an example, but the structure of the current sensor 100 illustrated in FIG. 1 or the current sensor 200 illustrated in FIG. 2 can also be similarly applied.

FIG. 7 illustrates a configuration in which the first substrate 310 and the second substrate 320 are inserted into a shielding case 730 and then the shielding case 730 is inserted into a mounting member 720. However, when the shielding case 730 is not used, the first substrate 310 and the second substrate 320 can be mounted by pushing them all the way to the bottom of the mounting member 720. In this case, there is no need to form the L-shaped grooves 316 at the four corners of the first substrate 310.

In the examples shown in FIGS. 8 and 9, a plate-type bus bar with a thickness of 2 mm and a width of 10 mm and bent into an L shape is used as the power line P, and the fastening portion 721 is formed on the side of the mounting member 720 so that the first substrate 310 and the second substrate 320 inserted into the mounting member 720 are mounted on the power line P. However, this is only one example for explanation, and by forming the fastening portion 721 on the side or bottom of the mounting member 720, it is also applicable to a straight bus bar, a circular bus bar, or a wire having an appropriate thickness.

In at least one embodiment of the present disclosure, the width of the mounting member 720 may be wider than the width of the power line P, but it is preferable that the width of each of the coils C1 to C4 constituting the sensor unit 311 be formed to correspond to the width of the power line P.

In FIG. 6, the plurality of via holes 312 are illustrated as being formed in two rows in a zigzag shape in the first direction, but this is an arrangement for connecting the plurality of via holes 312 in a spiral coil shape through the line patterning 313. However, as long as the plurality of via holes 312 can be connected in a spiral coil shape through the line patterning 313, they may be formed in two rows in a straight line instead of a zigzag shape.

In at least one embodiment of the present disclosure, as illustrated in FIG. 6, the plurality of via holes 312 are arranged at a first position in the x direction, and the plurality of via holes 312 are arranged at a second position in the x direction. Although the y-direction positions of the plurality of via holes 312 at the first position and the y-direction positions of the plurality of via holes 312 at the second position are different, the respective y-direction positions may be arranged to match.

In other words, when the plurality of via holes 312 are formed in two rows oriented in a straight line in the first direction, the number of via holes on one side may be formed by one more or one less as needed, and in any case, the line patterning 313 must connect the plurality of via holes 312 diagonally on at least one side, so the expression zigzag was used, but as long as they are formed in two rows oriented in a straight line, zigzag and straight line can be considered as the same form.

In at least one embodiment of the present disclosure, the line patterning 313 is formed on the conductor layers on both sides of the insulating layer so as to electrically connect the plurality of via holes 312 formed in two rows oriented in a zigzag shape in a spiral shape to form the coils C1 to C4 with the first direction as the central axis.

In at least one embodiment of the present disclosure, the first substrate 310 including at least one of the coils C1 to C4 formed by the plurality of via holes 312 and the line patterning 313 is configured such that its first surface is mounted in proximity to the power line P in a direction in which the central axes of the coils C1 to C4 intersect the power line for measuring current. Here, the configuration of being “closely mounted” can be considered to mean, for example, a configuration in which the first substrate 310 is mounted in contact with the inner wall surface of the current sensor 700 (or the mounting member 720 illustrated in FIG. 7).

That is, the current sensor according to at least one embodiment of the present disclosure can measure current flowing in the power line by mounting the first surface of the sensor unit in proximity to the power line without bypassing or cutting the power line for measuring current.

Although FIGS. 8 and 9 illustrate a plate-shaped busbar as an example of the power line P for measuring current, the current sensor according to at least one embodiment of the present disclosure can be applied to any type of power line, including plate-shaped or ring-shaped busbars and general conductors.

In at least one embodiment of the present disclosure, as illustrated in FIGS. 4 and 5, the sensor unit 311 includes a plurality of coils C1 to C4 whose central axes are formed parallel to each other, and the plurality of coils C1 to C4 are connected in parallel or in series.

Since the sensor unit 311 detects the amount of current flowing in the power line P by the induced current induced in the coils C1 to C4, the sensitivity can be improved as the amount of induced current increases. Therefore, the sensitivity can be improved by connecting the plurality of coils C1 to C4 whose central axes are formed parallel to each other in parallel to increase the amount of induced current, or by connecting them in series to increase the induced electromotive force.

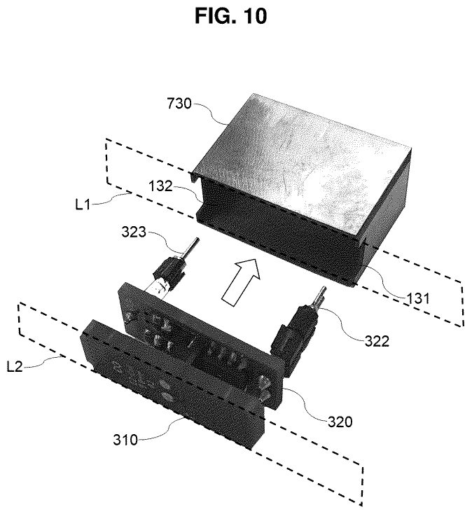

FIG. 10 is an exploded perspective view illustrating the assembly process of a current sensor according to at least one embodiment of the present disclosure.

In at least one embodiment of the present disclosure, the current sensor further includes a circuit unit mounted on the second substrate 320, electrically connected to the sensor unit formed on the first substrate 310, receiving output from the coils C1 to C4, and outputting a current signal representing the intensity of current flowing in the power line through predetermined signal processing.

The example illustrated in FIG. 10 illustrates a case in which the circuit unit is mounted on the separate second substrate 320, electrically connected to the sensor unit, receiving output from the coils C1 to C4, and outputting a current signal representing the intensity of current flowing in the power line through predetermined signal processing.

Here, the second substrate 320 is formed to have the same size as the portion of the first substrate 310, excluding both sides protruding in the second direction, and is formed to be connected to the first substrate 310 through predetermined fastening members and inserted into the interior of the shielding case 730.

Accordingly, when the first substrate 310 having the sensor unit formed thereon and the second substrate 320 having the circuit unit mounted thereon are physically and electrically connected through a predetermined fastening member (connection unit 340) and inserted into the shielding case 730 in the direction of the arrow shown in FIG. 10, the second substrate 320 is inserted into the interior of the shielding case 730 and the first substrate 310 is mounted in the shielding case 730 in such a way that both sides protruding in the second direction are fitted into the recessed portion 731 and fixed therein, thereby blocking the opening 732.

That is, when the first substrate 310 is fitted into the recessed portion 731 of the shielding case 730, as shown in FIG. 10, the surface L1 of the opening 732 of the shielding case 730 and the outer surface L2 of the first substrate 310 become approximately the same.

In at least one embodiment of the present disclosure, a current sensor includes a circuit unit including a sensor unit including coils C1 to C4 for detecting current flowing in a power line, a filter unit connected to the output terminal of the sensor unit for eliminating noise, and an amplifier unit for amplifying the signal passing through the filter unit.

The coils C1 to C4 of the current sensor are mounted in proximity to the power line through which current flows, thereby allowing a rotating magnetic field generated by the power line to enter the coil and to output a sinusoidal induced current.

The filter unit passes the induced current through a low-pass filter, passing low-frequency signals and removing high-frequency signals based on a predetermined frequency. The signal passing through the amplifier unit passes through a high-pass filter, removing DC noise and signals below a predetermined frequency.

The amplifier unit uses a differential amplifier to amplify the input signal by approximately 1,000 times, thereby outputting a sinusoidal wave. The amplification factor can be adjusted as needed.

In at least one embodiment of the present disclosure, a signal output terminal 323 for outputting a signal from the circuit unit to the outside and a power supply terminal 322 for supplying power to the circuit unit are electrically connected to the first substrate 310 or the second substrate 320.

In at least one embodiment of the present disclosure, the shielding case 730 includes a power supply port (not shown) for passing a power line for supplying power to the circuit unit and a signal output port (not shown) for passing a signal output line from the circuit unit.

In at least one embodiment of the present disclosure, the fastening portion 721 of the mounting member 720 includes a rail-shaped groove into which the power line P is inserted and fastened. That is, by configuring the current sensor 700 as illustrated in FIG. 7 and inserting the plate-shaped power line P into the rail-shaped groove as illustrated in FIG. 8, the current sensor 700 is mounted on the power line P so that the sensor unit is brought into proximity to the power line P, as illustrated in FIG. 9.

In at least one embodiment of the present disclosure, the fastening portion 721 of the mounting member 720 includes a clip-shaped groove into which the power line P is inserted and fastened.

This structure is configured to be rotatable outward by forming a bend (not shown) at the point where the L-shaped portion of the fastening portion 721 of the mounting member 720 shown in FIG. 7, which supports the power line P from the outside, meets the mounting member 720, and can be used, for example, in the case of a straight bus bar or annular bus bar rather than an L-shaped bus bar as shown in FIGS. 8 and 9.

In at least one embodiment of the present disclosure, the width of the mounting member 720 corresponds to the width of the power line P, and the width of the first substrate 310 in the first direction is formed to be smaller than the width of the power line P.

In at least one embodiment of the present disclosure, the mounting member 720 is formed such that the inner length (the inner length from the opening to the floor) in a third direction perpendicular to the first and second directions is equal to the outer length (the outer length from the opening to the floor) of the shielding case 730 in the third direction (see FIGS. 7 and 8).

By doing so, the current sensor 700 can be formed in which the shielding case 730 including the sensor unit and the circuit unit and the mounting member 720 are integrated.

In at least one embodiment of the present disclosure, the mounting member 720 is formed such that the inner length (the inner length from the opening to the floor) in a third direction perpendicular to the first and second directions is shorter than the outer length (the outer length from the opening to the floor) of the shielding case 730 in the third direction.

This structure has the advantage of facilitating separation of the shielding case 730 and the mounting member 720 in the event of a problem with the fastening portion 721 of the mounting member 720 or a problem with the sensor or circuitry.

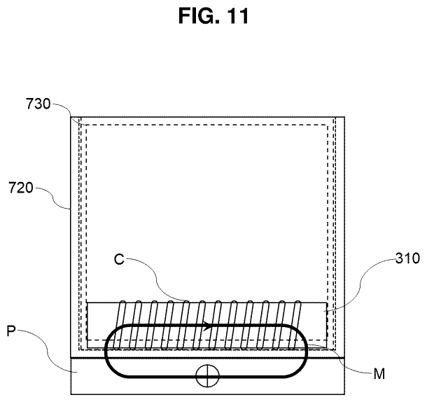

FIG. 11 is a cross-sectional side view showing a current sensor according to at least one embodiment of the present disclosure mounted on a power line P. In the example illustrated in FIG. 11, only the first substrate 310 is illustrated for convenience of explanation.

As illustrated in FIG. 11, when the first substrate 310 having the sensor unit formed thereon is mounted in a shielding case 730 in a form that covers the opening 732, and then the shielding case 730 is inserted into the mounting member 720 so that the first substrate 310 faces inward and the first substrate 310 is mounted on the power line P so that it is close to the power line P, the magnetic flux M generated when current flows in the power line P is converted into an induced current as it passes through the coil C of the sensor unit formed in the first substrate 310. That is, the coil C of the sensor unit functions as an induction coil that induces the magnetic flux M generated when current flows in the power line P.

When an alternating current flows through the power line P, the magnetic flux M generated around the power line P flows into the coil C, and the resulting change in magnetic flux inside the coil C is converted into an induced current or an induced electromotive force through the coil C and outputted. Therefore, by calculating this induced current or induced electromotive force, the amount of current flowing through the power line P can be obtained.

In at least one embodiment of the present disclosure, the shielding case 730 includes recessed portions 731 on both sides facing in the second direction of the opening 732 so that both sides protruding in the second direction perpendicular to the first direction of the first substrate 310 are fitted, and when both sides protruding in the second direction of the first substrate 310 are fitted into the recessed portions 731 of the opening 732, both sides in the first direction are inserted into the opening 732 to block the opening 732, so that when the shielding case 730 is mounted on the power line P so that the sensor part is close to the power line P, the shielding case 730 shields the outer surface of the sensor part (the side opposite to the power line P) and the power line P serves to shield the power line P side.

That is, the current sensor according to at least one embodiment of the present disclosure has a structure in which, when the first substrate 310 is mounted on the shielding case 730, inserted into the mounting member 720, and mounted on the power line P, the shielding case 730 and the power line P shield all directions of the sensor unit with the bottom surface of the mounting member 720 interposed therebetween.

With the above structure, the sensor unit is shielded on all sides while allowing the magnetic flux generated when current flows in the power line P to enter the coil C. Therefore, the width of the sensor unit (length in the first direction) needs to be set to be less than the width of the power line P.

According to the configuration of the present disclosure as described above, electromagnetic noise transmitted from the outside of the power line P is blocked by the shielding case 730, and the magnetic change generated in the power line P is mainly detected by being transmitted to the sensor unit as the magnetic flux M within the shielding case 730, thereby minimizing the influence of the external noise.

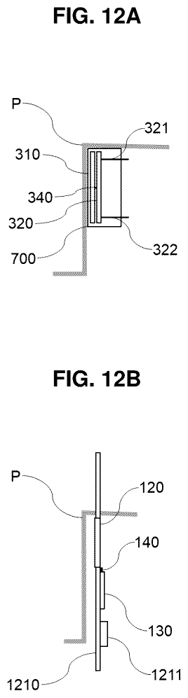

FIGS. 12A and 12B are side views each showing a configuration in which a current sensor according to at least one embodiment of the present disclosure is mounted on a power line P.

FIG. 12A shows a configuration in which, as illustrated in FIG. 9, the first substrate 310 and the second substrate 320 are electrically connected by a connection unit 340, such that the first substrate 310 is positioned closer to the power line P than the second substrate 320 and parallel to the power line P.

FIG. 12B shows a configuration in which the sensor unit 120, the circuit unit 130, and the connection unit 140 for electrically connecting the sensor unit 120 and the circuit unit 130 are formed on a controller substrate 1210 in a configuration in which the power line P passes through a hole formed in the controller substrate 1210 on which an MCU 1211 or the like is mounted.

That is, in FIG. 12B, a current sensor is configured using the controller board 1210 equipped with the MCU 1211 for detecting current flowing in the power line P and performing power management, instead of the substrate 110 illustrated in FIG. 1.

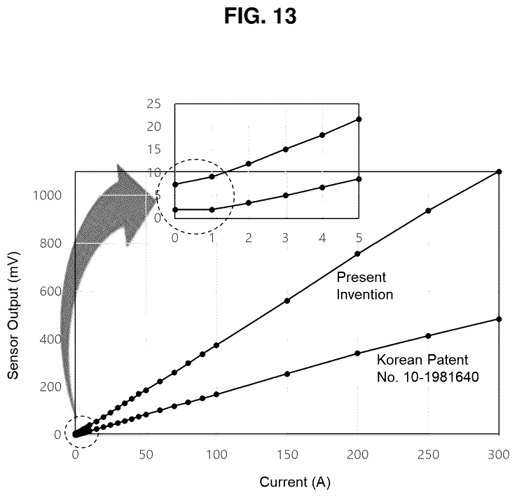

FIG. 13 is a measurement graph for comparing the current detection performance of a current sensor according to at least one embodiment of the present disclosure and a current sensor according to Korean Patent No. 10-1981640.

As illustrated in FIG. 13, in both cases, the sensor output increases linearly without saturation up to 300 A. However, when the area below 1 A is expanded, it can be seen that the current sensor according to at least one embodiment of the present disclosure linearly increases the sensor output, whereas the current sensor according to Korean Patent No. 10-1981640 shows no change in the sensor output.

That is, the current sensor according to at least one embodiment of the present disclosure exhibits a sensor output that increases linearly with increasing current.

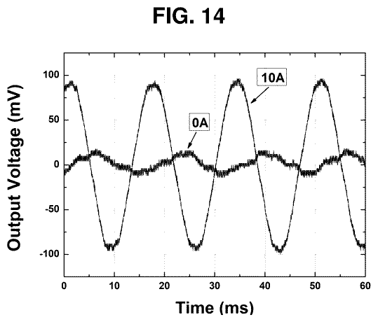

FIG. 14 is a measurement graph showing the noise characteristics of a current sensor according to at least one embodiment of the present disclosure.

The graph shown in FIG. 14 shows the output voltage waveform of a current sensor mounted on a power line, measured using an oscilloscope, when currents of 0 A and 10 A flow through the power line. While current sensors typically applied to busbars contain noise to the point where it is difficult to discern the sine wave shape, the current sensor, according to at least one embodiment of the present disclosure, outputs a distinct sine wave even at 0 A, demonstrating that it is virtually unaffected by noise.

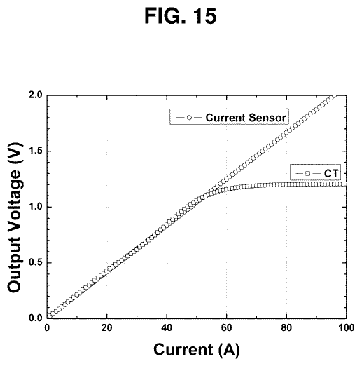

FIG. 15 is a measurement graph showing the unsaturated characteristics of a current sensor according to at least one embodiment of the present disclosure.

The graph shown in FIG. 15 compares the characteristics of a commercial CT with a rated specification of 40/5 A with a current sensor according to at least one embodiment of the present disclosure. As the current flowing through the wire increases, the current sensor, according to at least one embodiment of the present disclosure, exhibits unsaturated characteristics, while the CT exhibits saturated characteristics.

The current sensor illustrated in FIGS. 4 to 6 illustrates an example of forming a coil using a PCB, via holes with a conductive film formed on the inner wall, and line patterning. However, the coil used in the sensor unit may also be formed as an actual insulation-coated coil.

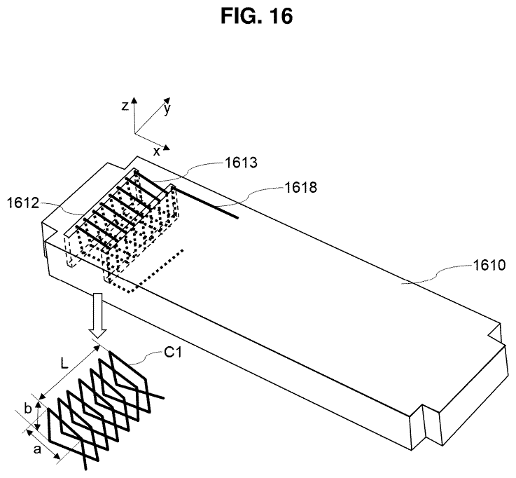

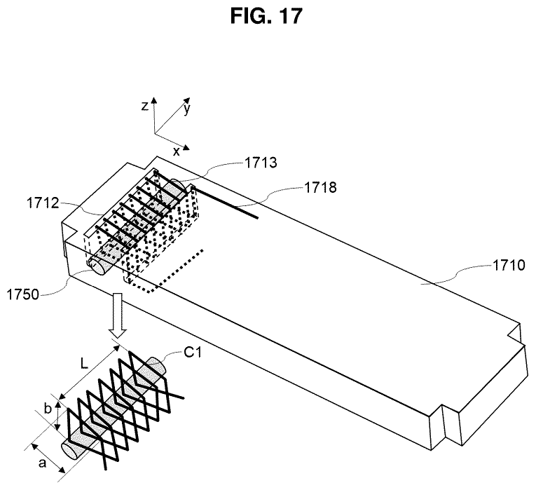

FIGS. 16 and 17 are perspective views illustrating the coil formation structure of the sensor unit of a current sensor according to at least one embodiment of the present disclosure.

As illustrated in FIG. 16, the current sensor according to at least one embodiment of the present disclosure includes a sensor unit including a substrate 1610 made of an insulating material, two rows of through-holes 1612 formed in parallel in a first direction on the substrate 1610, and at least one coil C1 formed by spirally winding an insulation-coated conductor 1613 through the two rows of through-holes 1612 so that the coil is oriented in the first direction.

The current sensor according to at least one embodiment of the present disclosure may have a structure similar to the current sensor illustrated in FIGS. 1 to 12, except that the coil used in the sensor unit is formed as an actual insulation-coated coil.

As illustrated in FIG. 17, a current sensor according to at least one embodiment of the present disclosure includes a sensor unit including at least one coil formed on a substrate 1710 as illustrated in FIG. 6 or FIG. 16 (in the example illustrated in FIG. 17, at least one coil C1 formed by spirally winding the insulated conductor 1713 through the two rows of through grooves 1712 formed in a first direction on the substrate 1710 and having the first direction as a central axis).

In at least one embodiment of the present disclosure, the sensor unit is formed of a coil C1 that functions as an induction coil and may optionally include an iron core 1750. While a coreless coil has the advantage of not being saturated, a coil having an iron core has the disadvantage of being saturated when the magnetic flux density of the iron core reaches its maximum, but has the advantage of increased sensitivity.

The iron core 1750 can be formed, for example, by inserting an iron core member between two insulating layers in accordance with the pattern of the coil C1 when forming the insulating layer of the substrate 1710 and then pressing the two insulating layers together. Alternatively, a sensor unit, such as that illustrated in FIG. 6 or FIG. 16, can be formed by drilling a hole in the interior of the coil C1 from the side and inserting the iron core member into the hole.

Even in the sensor units illustrated in FIGS. 16 and 17, when forming the line pattern for coil formation, the length of lines 1618, 1718 parallel to the power lines is formed as short as possible (or minimized).

As described above, according to at least one embodiment of the present disclosure, a current sensor can be provided that maintains high sensitivity when measuring current at commercial frequencies, minimizes the influence of noise, and miniaturizes the size of the sensor itself.

The present disclosure should not be limited to these embodiments but various changes and modifications are made by one ordinarily skilled in the art within the subject matter, the spirit and scope of the present disclosure as hereinafter claimed. Specific terms used in this disclosure and drawings are used for illustrative purposes and not to be considered as limitations of the present disclosure. Exemplary embodiments of the present disclosure have been described for the sake of brevity and clarity. Accordingly, one of ordinary skill would understand the scope of the claimed invention is not to be limited by the explicitly described above embodiments but by the claims and equivalents thereof.

What is claimed is:

1. A current sensor for measuring a current flowing through a power line, the current sensor comprising:
a sensor unit including at least one coil formed of a substrate including an insulating layer and a first conductor layer and a second conductor layer respectively formed on both surfaces of the insulating layer, a plurality of via holes each comprising a conductive film on an inner wall thereof formed so as to penetrate the insulating layer, the first conductor layer, and the second conductor layer, and a line patterning formed on the first and second conductor layers to electrically connect the plurality of via holes;
a circuit unit disposed in proximity to the sensor unit on the first conductor layer or the second conductor layer and configured to output a detection signal from the sensor unit to an outside; and
a connection unit configured to electrically connect the sensor unit and the circuit unit,
wherein a width of the sensor unit and a width of the circuit unit in a transverse direction of the power line, which is perpendicular to a longitudinal direction of the power line through which the current flows, are each formed to be equal to or less than a width of the power line,
wherein the circuit unit overlaps the power line, and
wherein the sensor unit and the circuit unit are aligned along the longitudinal direction of the power line.

2. The current sensor according to claim 1, wherein the coil includes therein a metal core at its center.

3. The current sensor according to claim 1, wherein the circuit unit includes at least a low-pass filter and an amplifier.

4. The current sensor according to claim 1, further comprising a mounting member made of an insulating material, configured in a box shape to accommodate both the sensor unit and the circuit unit, and comprising a fastening portion on an outer surface thereof to be fitted to a power line.

5. The current sensor according to claim 1, further comprising a shielding case made of a conductive material, configured in a box shape to accommodate both the sensor unit and the circuit unit, and comprising an opening on a first side thereof.

6. The current sensor according to claim 5, further comprising a mounting member made of an insulating material, configured in a box shape with one side open to allow the opening side of the shielding case to be inserted, and comprising a fastening portion on an outer surface thereof to be fitted to a power line.

7. A current sensor for measuring a current flowing through a power line, the current sensor comprising:
a sensor unit including at least one coil formed of a substrate including an insulating layer and a first conductor layer and a second conductor layer respectively formed on both surfaces of the insulating layer, a plurality of via holes each comprising a conductive film on an inner wall thereof formed so as to penetrate the insulating layer, the first conductor layer, and the second conductor layer, and a line patterning formed on the first and second conductor layers to electrically connect the plurality of via holes;
a circuit unit disposed in proximity to the sensor unit on the first conductor layer or the second conductor layer and configured to output a detection signal from the sensor unit to an outside; and
a connection unit configured to electrically connect the sensor unit and the circuit unit,
wherein a width of the sensor unit and a width of the circuit unit in a transverse direction of the power line, which is perpendicular to a longitudinal direction of the power line through which the current flows, are each formed to be equal to or less than a width of the power line,
wherein the circuit unit overlaps the power line, and
wherein the sensor unit and the circuit unit are aligned along the transverse direction of the power line.

8. The current sensor according to claim 7, wherein the coil includes therein a metal core at its center.

9. The current sensor according to claim 7, wherein the circuit unit includes at least a low-pass filter and an amplifier.

10. The current sensor according to claim 7, further comprising a mounting member made of an insulating material, configured in a box shape to accommodate both the sensor unit and the circuit unit, and comprising a fastening portion on an outer surface thereof to be fitted to a power line.

11. The current sensor according to claim 7, further comprising a shielding case made of a conductive material, configured in a box shape to accommodate both the sensor unit and the circuit unit, and comprising an opening on a first side thereof.

12. The current sensor according to claim 11, further comprising a mounting member made of an insulating material, configured in a box shape with one side open to allow the opening side of the shielding case to be inserted, and comprising a fastening portion on an outer surface thereof to be fitted to a power line.

13. A current sensor for measuring a current flowing through a power line, the current sensor comprising:
a sensor unit including at least one coil formed of a first substrate including an insulating layer and a first conductor layer and a second conductor layer respectively formed on both surfaces of the insulating layer, a plurality of via holes each comprising a conductive film on an inner wall thereof formed so as to penetrate the insulating layer, the first conductor layer, and the second conductor layer, and a line patterning formed on the first and second conductor layers to electrically connect the plurality of via holes;
a circuit unit formed on a second substrate of a same type as the first substrate and configured to output a detection signal from the sensor unit to an outside; and
a connection unit configured to electrically connect the sensor unit and the circuit unit,
wherein a width of the sensor unit and a width of the circuit unit in a transverse direction of the power line, which is perpendicular to a longitudinal direction of the power line through which the current flows, are each formed to be equal to or less than a width of the power line, and
wherein the first substrate and the second substrate are disposed so as to be stacked in a direction normal to each other.

14. The current sensor according to claim 13, wherein the coil includes therein a metal core at its center.

15. The current sensor according to claim 13, wherein the circuit unit includes at least a low-pass filter and an amplifier.

16. The current sensor according to claim 13, further comprising a mounting member made of an insulating material, configured in a box shape to accommodate both the sensor unit and the circuit unit, and comprising a fastening portion on an outer surface thereof to be fitted to a power line.

17. The current sensor according to claim 13, further comprising a shielding case made of a conductive material, configured in a box shape to accommodate both the sensor unit and the circuit unit, and comprising an opening on a first side thereof.

18. The current sensor according to claim 17, further comprising a mounting member made of an insulating material, configured in a box shape with one side open to allow the opening side of the shielding case to be inserted, and comprising a fastening portion on an outer surface thereof to be fitted to a power line.
